(19) United States
(12) Patent Application Publication
(10) Pub. No.: US 2025/0151436 A1
(43) Pub. Date: May 8, 2025

(54) IMAGE SENSING DEVICE INCLUDING MULTI-LAYERED SCATTERING PATTERN

(71) Applicant: PIXELPLUS CO., LTD., Seongnam-si (KR)

(72) Inventors: Ji Min LEE, Seongnam-si (KR); Youn Sub LIM, Suwon-si (KR)

(21) Appl. No.: 18/934,773

(22) Filed: Nov. 1, 2024

(30) Foreign Application Priority Data
Nov. 2, 2023 (KR) 10-2023-0150329

(51) Int. Cl. H01L 27/146

(52) U.S. Cl. CPC H10F 39/806; H10F 39/182; H10F 39/184; H10F 39/8053; H10F 39/807

(57) ABSTRACT

An image sensing device according to an embodiment of the present technology may include a scattering pattern and a pixel separating structure, in which two or more materials having different indices of refraction are vertically laminated in a trench. The scattering pattern may increase a travel distance of incident light whereby a quantum efficiency of pixels may be increased, and the pixel separation structure may reduce optical crosstalk between adjacent pixels.

### CROSS-REFERENCE TO RELATED APPLICATION

This application claims the benefit of priority to Korean Patent Application No. 10-2023-0150329, filed in the Korean Intellectual Property Office on Nov. 2, 2023, the entire contents of which are incorporated herein by reference.

### TECHNICAL FIELD

The present disclosure relates to an image sensing device including a scattering pattern and a pixel separating structure of a multi-material lamination structure.

### BACKGROUND

An image sensing device is a semiconductor device that converts an optical image into an electrical signal. The image sensing device includes a plurality of pixels that are arranged two-dimensionally. Each of the pixels may include a photodiode (PD) that converts incident light into an electrical signal.

Recently, with the development of the computer industry and the communication industry, a demand for image sensing devices has been gradually increasing in various fields, such as digital cameras, camcorders, personal communication systems (PCS), automotive devices, security cameras, medical micro cameras, or robots.

### SUMMARY

The present disclosure has been made to solve the above-mentioned problems occurring in the prior art while advantages achieved by the prior art are maintained intact.

An aspect of the present disclosure is to improve a scattering pattern and a pixel separating structure of an image sensing device to improve a quantum efficiency for light in a long wavelength area and reducing optical crosstalk between adjacent pixels.

The technical problems to be solved by the present disclosure are not limited to the aforementioned problems, and any other technical problems not mentioned herein will be clearly understood from the following description by those skilled in the art to which the present disclosure pertains.

According to an aspect of the present disclosure, an image sensing device includes a semiconductor substrate having a first surface and a second surface being opposite to the first surface, and including photoelectric conversion areas that photo-electrically converts incident light input to the first surface to generate photoelectric charges, a scattering pattern including a convexo-concave structure obtained by partially etching the first surface of the semiconductor substrate, and that scatters the incident light, and an anti-reflection layer formed on the scattering pattern, and the scattering pattern includes trench areas, in which materials having different indices of refraction are laminated in a vertical direction in a trench obtained by etching the semiconductor substrate in the convexo-concave structure; and protrusions located between the trench areas in the convexo-concave structure.

### BRIEF DESCRIPTION OF THE DRAWINGS

The above and other objects, features and advantages of the present disclosure will be more apparent from the following detailed description taken in conjunction with the accompanying drawings:

FIG. 1 is a plan view illustrating, by way of example, a planar structure of a pixel array of a back-side illumination structure according to embodiments of the present disclosure;

FIG. 2 is a cross-sectional view illustrating, by way of example, a cross-sectional structure, taken along line X-X′ of FIG. 1;

FIG. 3A is a view illustrating, by way of example, progressions of light depending on an incident angle of the light in a scattering pattern and a pixel separating structure of FIG. 2;

FIG. 3B is a view illustrating, by way of example, progressions of light depending on an incident angle of the light when a scattering pattern and a pixel separating structure are formed entirely of a single material (e.g., an anti-reflection layer material);

FIG. 4 is a view illustrating, by way of example, cross-sectional views of scattering patterns and pixel separating structures according to other embodiments of the present disclosure;

FIG. 5 is a view illustrating, by way of example, a structure of a scattering pattern according to another embodiment of the present disclosure; and

FIG. 6 is a view illustrating, by way of example, a structure of a scattering pattern according to another embodiment of the present disclosure.

### DETAILED DESCRIPTION

Hereinafter, embodiments of the present disclosure will be described in detail with reference to the accompanying drawings. In adding reference numerals to the components of the drawings, it is noted that the same components are denoted by the same reference numerals even when they are drawn in different drawings. Furthermore, in describing the embodiments of the present disclosure, when it is determined that a detailed description of related known configurations and functions may hinder understanding of the embodiments of the present disclosure, a detailed description thereof will be omitted.

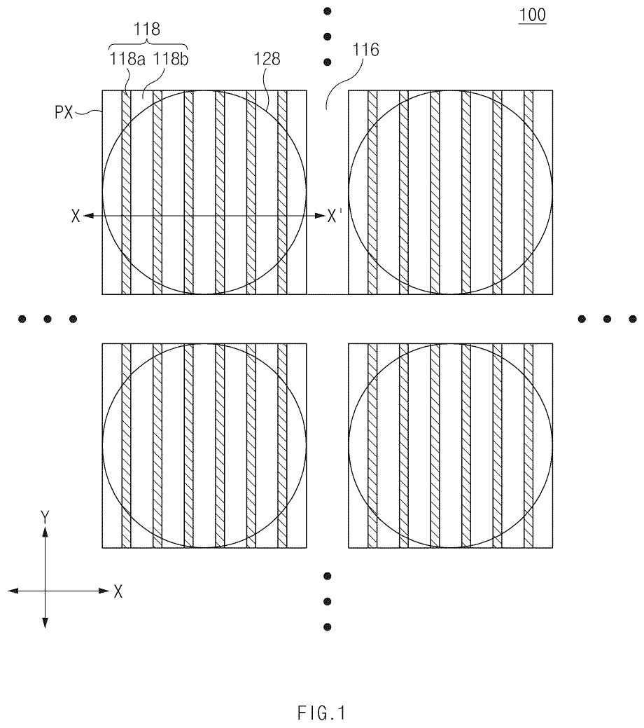

FIG. 1 is a plan view illustrating, by way of example, a planar structure of a pixel array of a back-side illumination structure according to embodiments of the present disclosure.

Referring to FIG. 1, an image sensing device may include a pixel array 100, in which a plurality of unit pixels PXs are arranged in a first direction (e.g., the “X” direction) and a second direction (e.g., the “Y” direction).

In the pixel array 100, a unit pixel (PX) area may be defined by a pixel separating structure 116. For example, the pixel separating structure 116 may be located between adjacent unit pixels PXs to surround the unit pixels PX.

The pixel separating structure 116 may include a trench isolation structure, in which insulators are buried in a trench that is obtained by etching a semiconductor substrate. For example, the pixel separating structure 116 may include a backside deep trench isolation (BDTI) structure. In the embodiment, the pixel separating structure 116 may include a multi-material lamination structure, in which a plurality of materials having different indices of refraction are laminated in a vertical direction.

Each of the unit pixels PX may include a scattering pattern 118 for scattering incident light.

The scattering pattern 118 may include a plurality of trench areas 118a and a plurality of protrusions 118b. The trench areas 118a and the protrusions 118b may be formed in a line type, in which they extend in the second direction, and the protrusions 118b may be located between the trench areas 118a. For example, the trench areas 118a and the protrusions 118b may be located alternately along the first direction. In FIG. 1, only a case, in which the scattering pattern 118 is formed in a line type, in which it extends in the second direction, is illustrated by way of example, but conversely, it may be formed in a line type, in which it extends in the first direction. Alternatively, the trench areas and the protrusions of the scattering pattern may be formed alternately in a concentric circle-like shape from a center of the pixel toward an edge area.

The trench areas 118a may include insulators that are buried in the trenches that are obtained by etching the substrate. For example, the trench areas 118a may include a multi-material lamination structure, in which a plurality of materials having different indices of refraction are laminated in the vertical direction in the trenches.

In each of the unit pixels PX, a lens layer 128, such as a microlens, may be formed on the scattering pattern 118.

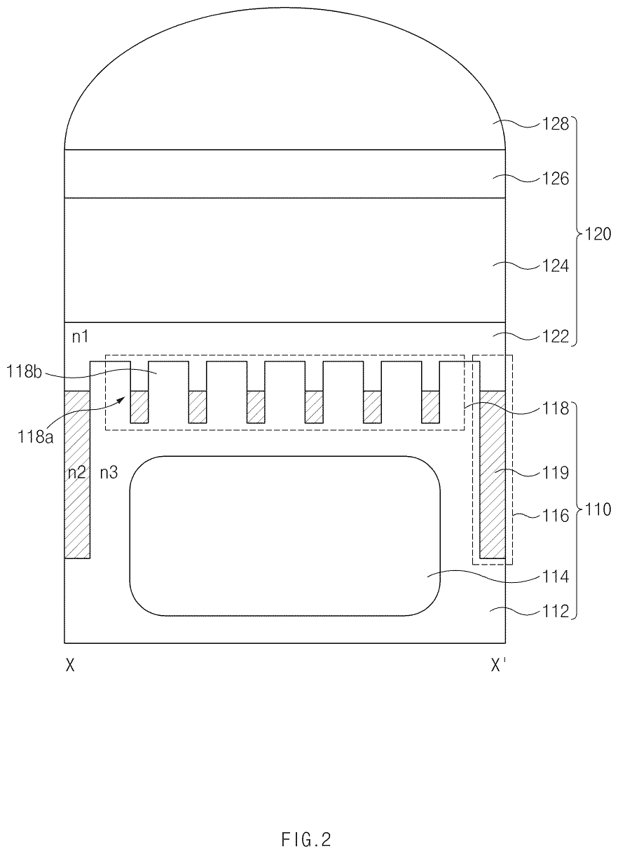

FIG. 2 is a cross-sectional view illustrating, by way of example, a structure of a cross-section, taken along cutting X-X′ of FIG. 1.

Referring to FIG. 2, an image sensing device may include a substrate layer 110 and a light transmission layer 120.

The substrate layer 110 may include a semiconductor substrate 112, a photoelectric conversion area 114, a pixel separating structure 116, and a scattering pattern 118.

The semiconductor substrate 112 may include a first surface (a rear surface), to which light is input, and a second surface (a front surface) that is opposite to the first surface. The semiconductor substrate may be in a single crystal state, and may include a silicon-containing material. The semiconductor substrate 112 may include impurities of a first type (e.g., a P type).

The photoelectric conversion area 114 may be located under the scattering pattern 118 in the semiconductor substrate 112, and may photoelectrically convert the light input through the scattering pattern 118 to generate photoelectric charges. The photoelectric conversion area 114 may include impurities of a second type (e.g., an N type). A photodiode may be formed through a junction of the second type photoelectric conversion area 114 and the first type semiconductor substrate 112.

The pixel separating structure 116 may be located between photoelectric conversion areas 114 in the semiconductor substrate 112 to separate the photoelectric conversion areas 114. The pixel separating structure 116 may include a trench isolation structure, in which an insulator is buried in the trench obtained by etching the semiconductor substrate 112. For example, the pixel separating structure 116 may include a backside deep trench isolation (BDTI) structure, in which insulators 119 and 122 having different indices of refraction are buried to be laminated in a vertical direction in the trench etched to a specific depth from the first surface (a rear surface) of the semiconductor substrate 112. Alternatively, the pixel separating structure 116 may include a deep trench isolation (DTI) structure, in which the insulators 119 and 122 having different indices of refraction are buried to be laminate in the vertical direction in the trench etched from the second surface (the front surface) of the semiconductor substrate 112.

The pixel separating structure 116 may include the insulators 119 and 122 having indices n1 and n2 of refraction n1, n2 that are lower than the index n3 of refraction of the semiconductor substrate 112 (n3>n1, n2). Then, the insulator 122 may be an anti-reflection layer 122 of the light transmission layer 120, which will be described below.

The insulators 119 and 122 of the pixel separating structure 116 may be laminated such that a material 119 having a relatively low index n2 of refraction is located under a material 122 having a relatively large index n1 of refraction n1 (n1>n2). For example, the pixel separating structure 116 may include silicon oxide (SiO2) 119 and hafnium oxide (HfO2) 122 that is laminated on the silicon oxide. Then, the hafnium oxide may be a portion of the anti-reflection layer 122 that will be described below. For example, the hafnium oxide formed in the pixel separating structure 116 may be formed such that the anti-reflection layer 122 extends into the trench of the pixel separating structure 116. The pixel separating structure 116 may be formed to pass through the semiconductor substrate 112.

The scattering pattern 118 may be formed on the first surface of the semiconductor substrate 112, and may scatter the incident light to increase a travel distance of the incident lights, and thus the incident lights may be absorbed easily in the photoelectric conversion area 114 without passing through the semiconductor substrate 112 whereby a light absorption rate in each of the unit pixels may be increased. The scattering pattern 118 may include a convexo-concave structure that is formed by partially etching the first surface of the semiconductor substrate 112.

The scattering pattern 118 may include a plurality of trench areas 118a and a plurality of protrusions 118b.

The trench areas 118a may include a structure, in which a plurality of insulators 119 and 122 having different indices of refraction are buried to be laminated in a vertical direction in a trench that is obtained by etching the semiconductor substrate 112 a specific depth in the convexo-concave structure of the scattering pattern 118. The trench areas 118a may include a lamination structure, such as the pixel separating structure 116, in which an insulator 119 having a relatively low index n2 of refraction is located under the insulator 122 having a relatively high index n1 of refraction. For example, the trench areas 118a may include silicon oxide 119 and hafnium oxide 122 that is laminated on the silicon oxide. In this case, the hafnium oxide may be a portion of the anti-reflection layer 122. For example, the hafnium oxide formed in the trench areas 118a may be formed such that the anti-reflection layer 122 extends into the trenches of the trench areas 118a.

The protrusions 118b may include semiconductor substrate areas that are located between the trench areas 118a in the convexo-concave structure of the scattering pattern 118. For example, the protrusions 118b may be portions that protrude relatively upward by etching portions, at which the trench areas 118a are formed on the first surface of the semiconductor substrate 112.

The protrusions 118b may include interfaces that contact the anti-reflection layer 122. For example, the protrusions 118b may include a horizontal interface that contacts the anti-reflection layer 122 and extends in the horizontal direction, and a vertical interface that contacts the anti-reflection layer 122 and extends in the vertical direction. In addition, the protrusions 118b may include a vertical interface that extends in the vertical direction while contacting the insulator 119. That is, the convexo-concave structure of the scattering pattern 118 may include a structure, in which a plurality of vertical interfaces having different critical angle features are formed on one vertical surface as the vertical surfaces of the protrusions 118b contact the materials 119 and 122 having different indices of refraction.

The insulators 119 formed in the trench areas 118a and the insulators 119 formed in the pixel separating structure 116 may be formed so that the levels of the upper surfaces thereof are the same. Furthermore, the insulators 119 of the trench areas 118a may be formed at a lower level than that of the upper surfaces of the protrusions 118b.

In the embodiment, by forming the insulator 119 with a low index of refraction only partially in the lower area of a trench area 118a of the scattering pattern 118, the travel distance of light may be further increased while the material of the anti-reflection layer 122 formed on the semiconductor substrate 112 is used as it is.

The light transmission layer 120 may include an anti-reflection layer 122, a filter layer 124, an overcoating layer 126, and a lens layer 128.

The anti-reflection layer 122 may ensure that the light input through the filter layer 124, the overcoating layer 126, and the lens layer 128 is not reflected and is easily transmitted toward the photoelectric conversion area 114. Furthermore, the anti-reflection layer 122 may serve as a planarization layer for removing steps caused by the structures formed on the substrate layer 110.

The anti-reflection layer 122 may be formed on the scattering pattern 118 and the pixel separating structure 116 while being a portion of the scattering pattern 118 and the pixel separating structure 116. For example, the anti-reflection layer 122 may be formed to extend to an upper side of the scattering pattern 118 and the pixel separating structure 116 while being laminated on the insulator 119 in the corresponding trenches such that the trenches of the trench areas 118a and the trenches of the pixel separating structure 116 are buried.

The anti-reflection layer 122 may include an insulator having a higher index of refraction than those of the insulator 119 of the trench area 118a and the pixel separating structure 116. For example, the anti-reflection layer 122 may include hafnium oxide.

The filter layer 124 may be formed on the anti-reflection layer 122 to overlap the photoelectric conversion area 114, and may filter and transmit the incident light. The filter layer 124 may include optical filters that are formed to correspond to the unit pixel PX, respectively. In FIG. 2, only one filter corresponding to one unit pixel is illustrated for convenience of description, but the filter layer 124 may include red color filters that pass red light, green color filters that pass green light, and blue color filters that pass blue light. The color filters may be arranged in a Bayer pattern or other various pattern forms. The filter layer 124 may include a filter that passes long-wavelength light, such as infrared (IR or NIR). Alternatively, when the image sensing device is a mono sensor that uses black-and-white images, the filter layer 124 may not be formed.

The overcoat layer 126 may be formed on the color filter layer 124. The overcoat layer 126 may be formed of the same material as that of the lens layer 128, and may serve as a planarization layer for removing a step generated on an upper surface of the color filter layer 124.

The lens layer 128 may condense the incident light so that the incident light is directed to the photoelectric conversion area 114. The lens layer 128 may include a plurality of micro lenses that are formed for the respective unit pixels PX.

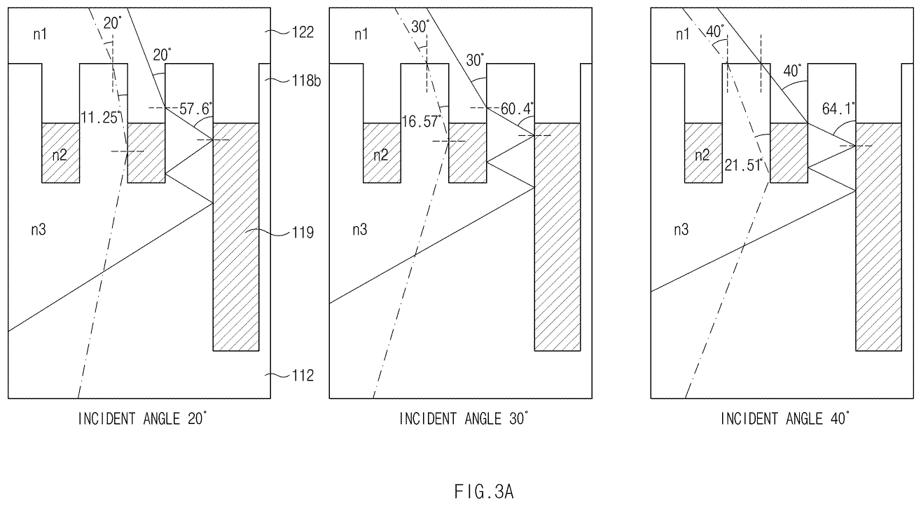

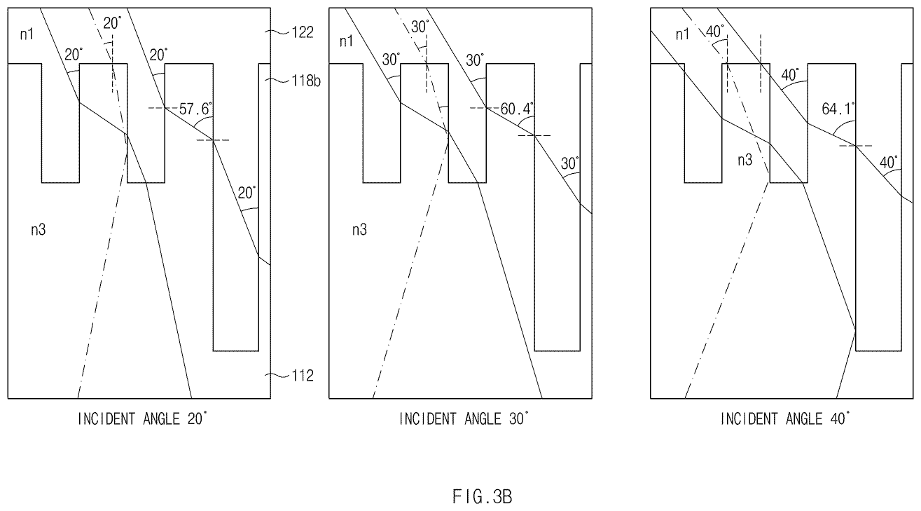

FIG. 3A is a view illustrating, by way of example, progressions of light depending on an incident angle of the light in a scattering pattern and a pixel separating structure of FIG. 2, and FIG. 3B is a view illustrating, by way of example, progressions of light depending on an incident angle of the light when a scattering pattern and a pixel separating structure are formed entirely of a single material (e.g., an anti-reflection layer material).

In the embodiment, it is described, by way of example, that the incident light has a long wavelength area of 850 nm, the anti-reflection layer 122 is hafnium oxide, and the insulator 119 is silicon oxide.

Referring to FIGS. 3A and 3B, a horizontal interface and a vertical interface may be formed between the anti-reflection layer 122 and the protrusion (a silicon substrate) 118b of the scattering pattern 118. In FIGS. 3A and 3B, a dashed line is an example of a progression of light that has passed through the anti-reflection layer 122 and is input to the horizontal interface between the anti-reflection layer 122 and the protrusion 118b, and a solid line is an example of a progression of light that has passed through the anti-reflection layer 122 and is input to the vertical interface between the anti-reflection layer 122 and the protrusion 118b.

Light that is input at a specific angle may be refracted due to the difference in the index of refraction from the protrusion 118b that is a silicon material after passing through the anti-reflection layer 122. Then, the incident light may be input to the horizontal interface and the vertical interface to be refracted.

First, in an exemplary description of the light (indicated by a dashed line) that is input to the horizontal interface between the anti-reflection layer 122 and the protrusion 118b in FIG. 3A, because the index n3 of refraction of the silicon that is the protrusion 118b is approximately 3.6 and the index n1 of refraction of the hafnium oxide that is the anti-reflection layer 122 is approximately 2.0, the light input at 20°, 30°, and 40° may be refracted to 11.25°, 16.57°, and 21.51° at the horizontal interface between the anti-reflection layer 122 and the protrusion 118b, respectively, and then may reach the vertical interface between the protrusion 118b and the insulator 119.

The index n2 of refraction of the silicon-oxide insulator 119 is approximately 1.4, so a maximum incident angle for total reflection at the vertical interface between silicon and silicon-oxide is 66.56°. Then, the maximum incident angle (66.56°) is an angle that is obtained by considering the critical angle for satisfying the total reflection condition. The critical angle is a starting point of the angle, at which the angle of refracted light becomes 90° when light is input from a material with a high index of refraction to a material with a low index of refraction, and may be calculated by applying a ratio of indices of refraction silicon and silicon-oxide an to arcsine function of {arcsin(n2/n3)}, and the maximum incident angle may be obtained by using the difference between the angle of a normal line at the vertical interface (90°) and a critical angle of silicon and silicon-oxide {90°−arcsin(n2/n3)}.

Because the incident angles (11.25°, 16.57°, and 21.51°) of the light input to the vertical interface between the protrusion 118b and the insulator 119 are all smaller than the maximum incident angle (66.56°), the light may be totally reflected and transmitted to the photoelectric conversion area 114.

The embodiment may improve the optical characteristics of the pixels by using the critical angle feature.

Next, in a description of the light input to the vertical interface between the anti-reflection layer 122 and the protrusion 118b in FIG. 3A, the light input to the vertical interface between the anti-reflection layer 122 and the protrusion 118b at 20°, 30°, and 40° may be refracted to 57.6°, 60.4°, and 64.1°, respectively. That is, the refraction angle may be significantly increased compared to the incident angle due to the vertical structure of the interface. Although the refraction angle is increased, the light may be totally reflected and transmitted to the adjacent trench area 118a because the refraction angles (57.6°, 60.4°, and 64.1°) are all smaller than the maximum incident angle (66.56°)at the vertical interface between silicon and silicon-oxide.

The totally reflected light continues to be totally reflected between the trench areas 118a or between the trench area 118a and the pixel separating structure 116 in proportion to the depths of the trenches of the trench area 118a and the pixel separating structure 116 whereby the travel distance may be increased and ultimately the light may be transmitted to the photoelectric conversion area 114. That is, the travel distance of the long-wavelength light of 850 nm also increases in the semiconductor substrate 112 due to the intensities of light of the scattering pattern 118 and the pixel separating structure 116 so that the long-wavelength light that passes through the semiconductor substrate 112 may be decreased and the long-wavelength light absorbed in the photoelectric conversion area 114 may be increased, whereby a light utilization efficiency (quantum efficiency) in the corresponding unit pixel may be increased.

As in FIG. 3B, even when the trench area 118a of the scattering pattern 118 and the pixel separating structure 116 are both formed of only a single material (e.g., hafnium oxide) that is the material of the anti-reflection layer 122, the refraction angles (11.25°, 16.57°, and 21.51°) of the light that has passed through the horizontal interface between the anti-reflection layer 122 and the protrusion 118b are smaller than the maximum incident angle (55.21) for total reflection at the vertical interface between silicon and hafnium oxide so that all of the lights may be totally reflected at the vertical interface and transmitted to the photoelectric conversion area 114.

However, when the incident light is initially input to the vertical interface between silicon and hafnium oxide and is refracted to 57.6°, 60.4°, and 64.1°, and then is input again to the vertical interface between silicon and hafnium oxide, unlike the case of FIG. 3A, the incident angle of the light is greater than the maximum allowable incident angle (55.21°)for satisfying the total reflection condition considering the critical angle formed at the interface between silicon and hafnium oxide so that the light is not totally reflected at the vertical interface and is refracted, and may pass through the trench area 118b or the pixel separating structure 116. Then, when the refraction occurs in an area that is adjacent to the pixel separating structure 116, the light may pass through the pixel separating structure 116 and may be transmitted to the photoelectric conversion area of another adjacent unit pixel. The light transmitted to the adjacent other unit pixels in this way may act as an optical crosstalk noise (crosstalk) element and degradation cause a of the characteristics of the adjacent unit pixels.

As described above, in the embodiment, in the trench area 118a and the pixel separating structure 116, a specific upper area is formed with the anti-reflection layer 122, and the insulator 119 having a lower index of refraction than that of the anti-reflection layer 122 is partially formed in a lower area so that vertical interfaces having different critical angle features may be formed in one vertical structure (a vertical surface) whereby a quantum efficiency of the image sensing device may be improved and the optical crosstalk noise between adjacent pixels may be decreased.

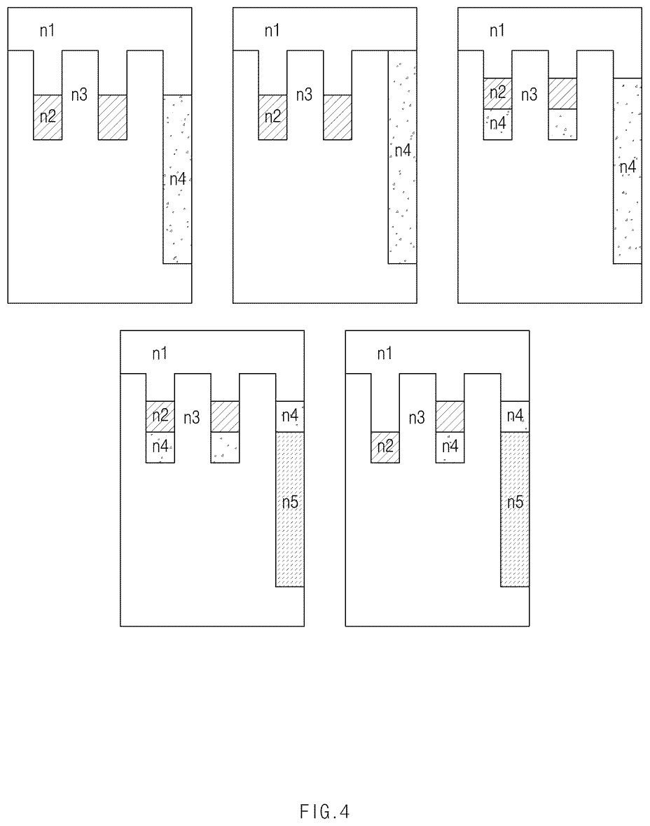

FIG. 4 is a view illustrating, by way of example, cross-sectional views of scattering patterns and pixel separating structures according to other embodiments of the present disclosure.

In the above-described embodiment, the structure, in which two materials having different indices n1 and n2 of refraction are laminated in the vertical direction in the same shape in the trench area 118a of the scattering pattern 118 has been described. However, the trench areas and the pixel separating structure may include a structure, in which two or more materials having different indices n1, n2, n4, and n5 of refraction are laminated in various forms, as in FIG. 4. However, even in this case, a condition that a material having a relatively lower index of refraction is located below a material having a relatively higher index of refraction has to be satisfied (n3>n1>n2>n4>n5).

Furthermore, in the above-described embodiment of FIG. 2, the case, in which the trench area 118a of the scattering pattern 118 and the pixel separating structure 116 include the same lamination structure, has been described, but as in FIG. 4, at least portions of the trench areas and the pixel separating structure may be formed of different materials and may include different lamination structures. For example, the pixel separating structure may include a material having a lower index of refraction than those of the materials laminated in the trench areas.

Furthermore, among the trench areas, the trench area that is adjacent to the pixel separating structure and the trench areas that are located inside it may be formed with different lamination structures. For example, the first trench area that is adjacent to the pixel separating structure may include a structure, in which three material layers having different indices of refraction are laminated, and the second trench area that is adjacent to the first trench area on the opposite side to the pixel separating structure may include a structure, in which two material layers having different indices of refraction are laminated.

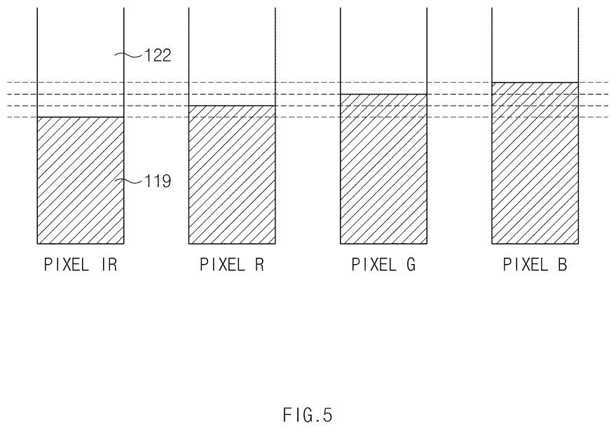

FIG. 5 is a view illustrating, by way of example, a structure of a scattering pattern according to another embodiment of the present disclosure.

Referring to FIG. 5, heights of the insulator 119 formed on a lower side in the trench areas 118a of the scattering pattern 118 may be formed differently depending on the characteristics of the filter layer 124 formed in the corresponding unit pixel.

For example, the unit pixel may include any one of a red color filter, a green color filter, a blue color filter, and an infrared (or near-infrared) filter, and the visual rays of the corresponding colors have different wavelengths, and the infrared rays also have different wavelengths from those of the visual rays. That is, the wavelengths of the lights input to the corresponding unit pixel may be different depending on the type of the color filter, and the refraction angles of the corresponding lights may be different accordingly.

Accordingly, in the embodiment, by changing the height of the insulator 119 in correspondence to the wavelength of the corresponding incident light depending on the types of the color filters formed on the unit pixels (pixel R, pixel G, pixel B, and pixel IR), crosstalk between the adjacent unit pixels may be prevented and the scattering characteristics of the incident light may be improved whereby the quantum efficiency of the image sensing device may be improved.

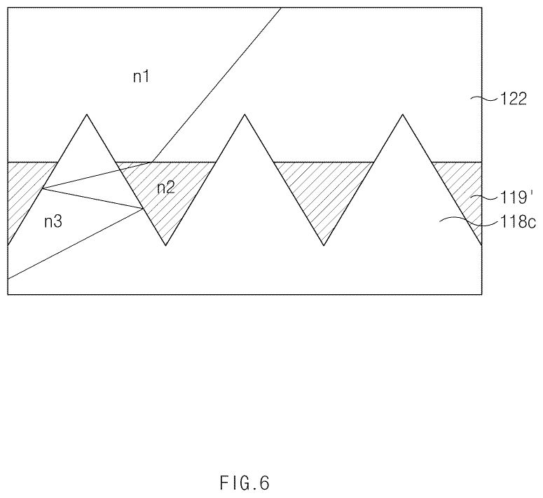

FIG. 6 is a view illustrating, by way of example, a structure of a scattering pattern according to another embodiment of the present disclosure.

Referring to FIG. 6, the protrusion 118c of the scattering pattern 118 may be formed in a form, in which a width of a vertical cross-section thereof becomes smaller as it goes upward. For example, the protrusion 118c may include a convexo-concave structure, such as a triangular pyramid, a square pyramid, or a hemisphere.

Unlike the case, in which the area between the protrusion 118c is completely filled with the anti-reflection layer 122, some of the incident lights may be input to the interface between the anti-reflection layer 122 and the insulator 119′ and be refracted in the structure of the embodiment. The light refracted at the interface between the anti-reflection layer 122 and the insulator 119′ is totally reflected within the protrusion 118c so that the travel distance is increased whereby the quantum efficiency may be improved.

The image sensing device according to an embodiment of the present disclosure may improve a quantum efficiency by allowing the incident light in a long wavelength area to be easily absorbed in the photoelectric conversion area, and may reduce optical crosstalk between adjacent pixels.

The above description is a simple exemplary description of the technical spirits of the present disclosure, and an ordinary person in the art, to which the present disclosure pertains, may make various corrections and modifications without departing from the essential characteristics of the present disclosure.

Therefore, the embodiments disclosed in the present disclosure are not for limiting the technical spirits of the present disclosure but for describing them, and the scope of the technical spirits of the present disclosure is not limited by the embodiments. The protection scope of the present disclosure should be construed by the following claims, and all the technical spirits in the equivalent range should be construed as being included in the scope of the present disclosure.

What is claimed is:

1. An image sensing device comprising:
a semiconductor substrate having a first surface and a second surface being opposite to the first surface, and including photoelectric conversion areas configured to photo-electrically convert incident light input to the first surface to generate photoelectric charges;
a scattering pattern including a convexo-concave structure obtained by partially etching the first surface of the semiconductor substrate, and configured to scatter the incident light; and
an anti-reflection layer formed on the scattering pattern,
wherein the scattering pattern includes:
trench areas, in which materials having different indices of refraction are laminated in a vertical direction in a trench obtained by etching the semiconductor substrate in the convexo-concave structure; and
protrusions located between the trench areas in the convexo-concave structure.

2. The image sensing device of claim 1, wherein the trench areas include:
a first material layer, in which the anti-reflection layer extends to the trench; and
a second material layer located under the first material layer to contact the first material layer, and of which an index of refraction is lower than that of the first material layer.

3. The image sensing device of claim 2, wherein the protrusions include:
a horizontal interface extending in a horizontal direction to contact the anti-reflection layer;
a first vertical interface extending in a vertical direction to contact the first material layer; and
a second vertical interface extending in a vertical direction from the first vertical interface, and contacting the second material layer.

4. The image sensing device of claim 2, wherein the trench areas further include:
a third material layer located under the second material layer to contact the second material layer, and of which an index of refraction is lower than that of the second material layer.

5. The image sensing device of claim 4, further comprising:
pixel separating structures located between the photoelectric conversion areas,
wherein the pixel separating structures include:
the first material layer; and
the third material layer located under the first material layer to contact the first material layer.

6. The image sensing device of claim 5, wherein the pixel separating structures further include:
a fourth material layer located under the third material layer to contact the third material layer, and of which an index of refraction is lower than that of the third material layer.

7. The image sensing device of claim 2, further comprising:
pixel separating structures located between the photoelectric conversion areas,
wherein the pixel separating structures include:
the first material layer; and
a third material layer located under the first material layer to contact the first material layer, and of which an index of refraction is lower than that of the third material layer.

8. The image sensing device of claim 2, further comprising:
a filter layer located on the semiconductor substrate to overlap the photoelectric conversion areas, and including color filters of different colors,
wherein the second material layer is formed such that a level of an upper surface thereof varies depending on colors of the color filters.

9. The image sensing device of claim 8, wherein the filter layer further includes:
an infrared ray filter configured to filter and transmit an infrared ray, and
wherein the second material layer corresponding to the infrared ray filter is formed such that a level of an upper surface thereof is different from that of the second material layer corresponding to the color filters.

10. The image sensing device of claim 1, further comprising:
pixel separating structures located between the photoelectric conversion areas,
wherein the trench areas include:
a first trench area located adjacent to the pixel separating structures; and
a second trench area located adjacent to the first trench area on an opposite side to the pixel separating structures, and
wherein the materials are laminated differently in the first trench area and the second trench area.

11. The image sensing device of claim 10, wherein different numbers of materials are laminated in the first trench area and the second trench area.

12. The image sensing device of claim 1, wherein the protrusions have a shape, of which a width on a vertical cross-section becomes smaller as it goes upward.
